(19) United States
(12) Patent Application Publication
(10) Pub. No.: US 2025/0015396 A1
(43) Pub. Date: Jan. 9, 2025

(54) ALKALI METAL THERMAL-TO-ELECTRIC CONVERTER HAVING LARGE EFFECTIVE IONIZATION AREA

(71) Applicant: Korea Institute of Energy Research, Daejeon (KR)

(72) Inventors: In Sub HAN, Nonsan-si (KR); Wook Hyun LEE, Daejeon (KR); Ji Haeng YU, Daejeon (KR); Se Young KIM, Daejeon (KR); Sun Dong KIM, Sejong-si (KR); Jong Won CHOI, Daejeon (KR); Tae Woo KIM, Daejeon (KR); Dae Gyun LEE, Daejeon (KR)

(73) Assignee: Korea Institute of Energy Research, Daejeon (KR)

(21) Appl. No.: 18/763,711

(22) Filed: Jul. 3, 2024

(30) Foreign Application Priority Data
Jul. 4, 2023 (KR) 10-2023-0086299

(51) Int. Cl. H01M 14/00

(52) U.S. Cl. CPC H01M 14/00; H01M 2300/0065

(57) ABSTRACT

An embodiment provides an alkali metal thermal-to-electric converter including a thermal-to-electric conversion cell including three layers including an anode layer, a solid electrolyte layer, and a cathode layer, having a convex-concave shape with alternately appearing concave and convex portions, and configured to move alkali metal ions through the solid electrolyte layer, a high temperature portion that supplies a high temperature alkali metal fluid to the anode layer of the thermal-to-electric conversion cell, and a low temperature portion that condenses the alkaline metal fluid discharged to the cathode layer of the thermal-to-electric conversion cell to a low temperature and moves the alkaline metal fluid to the high temperature portion.

### CROSS REFERENCE TO RELATED APPLICATION

This application claims the benefit of and priority to Korea Patent Application No. 10-2023-0086299, filed on Jul. 4, 2023, the entire disclosure(s) of which is hereby incorporated herein by reference in its entirety.

### FIELD OF TECHNOLOGY

The present embodiment relates to an alkali metal thermal-to-electric converter.

### BACKGROUND

A thermal-to-electric converter (AMTEC; Alkali Metal Thermal-to-Electric Conversion) is a device that converts thermal energy into electrical energy. The thermal-to-electric converter has been mainly developed as a high-efficiency thermal-to-electric converter that can be used for long-term space missions of a space probe, astronomical observation equipment, or the like.

The thermal-to-electric converter operates using an alkali metal and electrochemical cells. An alkali metal that is mainly used is sodium (Na) or potassium (K). The thermal-to-electric converter is a type of thermoelectrochemical cell and converts heat of the alkali metal into electrical energy.

An operating principle of the thermal-to-electric converter is as follows. First, the alkali metal is heated into a fluid state. The fluid alkali metal is then electrochemically activated within the cell. The alkali metal moves toward the cathode and is responsible for electrical conduction between an anode and the cathode. This movement is driven by thermal gradient caused by heat conduction.

Electrical conduction between the cathode and the anode is converted into electrical energy and can be used in an external circuit. The converted electrical energy may be utilized for various missions such as supply of power to a probe or space equipment.

The thermal-to-electric converter has high efficiency and durability, and can stably operate in a poor environment. Further, since the thermal-to-electric converter is silent and does not vibrate, the thermal-to-electric converter can assist in success of several missions.

However, a current thermal-to-electric converter has several problems, which limit commercialization.

FIG. 1 is a configuration diagram of a thermal-to-electric converter of the related art.

Referring to FIG. 1, a thermal-to-electric converter 1 includes a thermal-to-electric conversion cell 10, a case 20, a condensation unit 30, an evaporation unit 240, a heat source 80, and a circulation wick 61.

Heat supplied from the heat source 80 heats an alkali metal fluid contained in the evaporation unit 240. This alkali metal fluid moves through the thermal-to-electric conversion cell 10, condenses in the condensation unit 30, and returns to the evaporation unit 240 through the circulation wick 61.

Direct factors having an influence on the performance and efficiency of the thermal-to-electric converter 1 include a temperature of a BASE (Beta double prime Alumina Solid Electrolyte) that is a solid electrolyte, a temperature of the condensation unit, a current density of an electrode, and an effective ionization area of the BASE.

Since an output of the thermal-to-electric converter 1 is generated in the form of a low voltage and high current, a large capacity through increase in an area is necessary for economic power generation.

Meanwhile, in order to increase an area of the BASE in which an alkaline metal comes into contact with a beta-based solid electrolyte with high ionic conductivity at high temperature and undergoes an ion exchange process, it is necessary to have a fundamental structure that effectively enables an ionization process, a position and structure in which an alkali metal exists as a fluid or gas at each position in a thermal-to-electric converter, and a structure in which circulation in a system of the alkaline metal for a continuous power generation process is possible, and it is necessary to perform a smooth operation while satisfying the structures even in a process of increasing an area.

The discussions in this section are only to provide background information and do not constitute an admission of prior art.

### SUMMARY

In view of this background, an object of the present embodiment is to provide a technology for increasing an effective ionization area of a thermal-to-electric conversion cell in one aspect. In another aspect, an object of the present embodiment is to provide a structure capable of easily achieving current collection in a large-area thermal-to-electric conversion cell.

In order to achieve the above-described object, an embodiment provides an alkali metal thermal-to-electric converter including: a thermal-to-electric conversion cell including three layers of an anode layer, a solid electrolyte layer, and a cathode layer and having a convex-concave shape with alternately appearing concave and convex portions, the thermal-to-electric conversion cell being configured to move alkali metal ions through the solid electrolyte layer; a high temperature portion configured to supply a high temperature alkali metal fluid to the anode layer of the thermal-to-electric conversion cell; and a low temperature portion configured to condense the alkaline metal fluid discharged to the cathode layer of the thermal-to-electric conversion cell to a low temperature and move the alkaline metal fluid to the high temperature portion.

In the thermal-to-electric conversion cell, a plurality of concave portions and a plurality of convex portions may alternately appear in a horizontal direction and a vertical direction.

In the thermal-to-electric conversion cell, the plurality of concave portions and the plurality of convex portions may have a square matrix form of one of 3×3, 5×5, and 7×7.

The high temperature portion may be disposed on the upper side and the low temperature portion may be disposed on the lower side.

The alkali metal fluid condensing in the low temperature portion may be moved to the high temperature portion through a capillary circulation wick.

The capillary circulation wick may be connected to a condensation tube formed in the low temperature portion, and a funnel structure having an upper portion wider than a lower portion may be disposed on the upper side of the condensation tube.

A porous anode current collector may be disposed in contact with the cathode layer of the thermal-to-electric conversion cell, and a porous cathode current collector may be disposed in contact with the anode layer.

A conductive lower case may come into contact with the outermost anode current collector.

An insulator may be disposed between the thermal-to-electric conversion cell and an upper case.

The thermal-to-electric converter may further include a cathode current collection structure having a plurality of cathode current collection pins inserted into a plurality of concave portions when viewed from the high temperature portion side.

The thermal-to-electric converter may further include an anode current collection structure having a plurality of anode current collection pins inserted into a plurality of concave portions when viewed from the low temperature portion side.

The alkali metal fluid may be sodium (Na) or potassium (K).

A heat supply unit may be disposed to surround upper and side surfaces of the high temperature portion.

A high temperature sodium fluid from nuclear power generation may be supplied to the heat supply unit.

In the high temperature portion, the alkali metal fluid may come into contact with the anode layer of the thermal-to-electric conversion cell in a molten form.

As described above, according to the present embodiment, it is possible to provide a large-capacity thermal-to-electric converter by increasing the effective ionization area of the thermal-to-electric conversion cell. According to the present embodiment, it is possible to provide a thermal-to-electric converter capable of easily achieving current collection while having a large effective ionization area.

### BRIEF DESCRIPTION OF THE DRAWINGS

In order that the disclosure may be well understood, there are now described various forms thereof, given by way of example, reference being made to the accompanying drawings, in which:

FIG. 1 is a configuration diagram of a thermal-to-electric converter of the related art;

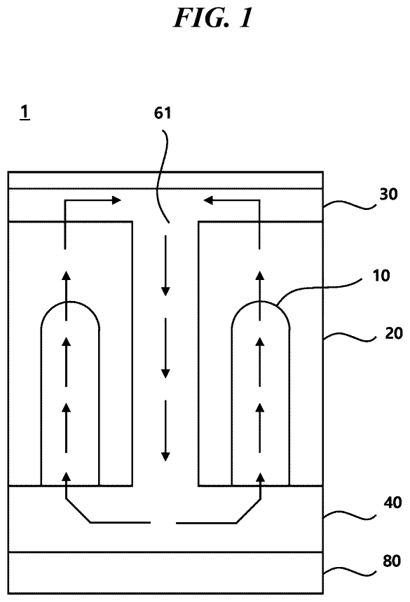

FIG. 2 is a configuration diagram of a thermal-to-electric converter according to an embodiment;

FIG. 3 is a diagram illustrating a thermal-to-electric conversion cell according to an embodiment;

FIG. 4 is a cross-sectional view of a first example of the thermal-to-electric conversion cell according to the embodiment;

FIG. 5 is a cross-sectional view of a second example of the thermal-to-electric conversion cell according to the embodiment;

FIG. 6 is a cross-sectional view of a third example of the thermal-to-electric conversion cell according to the embodiment;

FIG. 7 is a cross-sectional view of a fourth example of the thermal-to-electric conversion cell according to the embodiment;

FIG. 8 is a diagram illustrating a current collection structure according to an embodiment;

FIG. 9 is a cross-sectional view of a cathode current collection structure according to an embodiment; and

FIG. 10 is a cross-sectional view of an anode current collection structure according to an embodiment.

### DETAILED DESCRIPTION

Hereinafter, some embodiments of the present disclosure will be described in detail with reference to illustrative drawings. When components in each drawing are denoted by reference signs, it should be noted that the same components are denoted by the same reference signs as much as possible even if the components are shown in different drawings. Further, when a determination is made that detailed description of related known configurations or functions may obscure the gist of the present disclosure in describing the present disclosure, detailed description thereof will be omitted.

Further, terms such as first, second, A, B, (a), and (b) may be used in describing components of the present disclosure. These terms are only used to distinguish the components from other components, and nature or order of the components is not limited by the terms. When a certain component is described as being “connected”, “combined,” or “coupled” to another component, the component may be directly connected or coupled to the other component, but it will be understood that yet another component may be “connected”, “combined,” or “coupled” between the respective components.

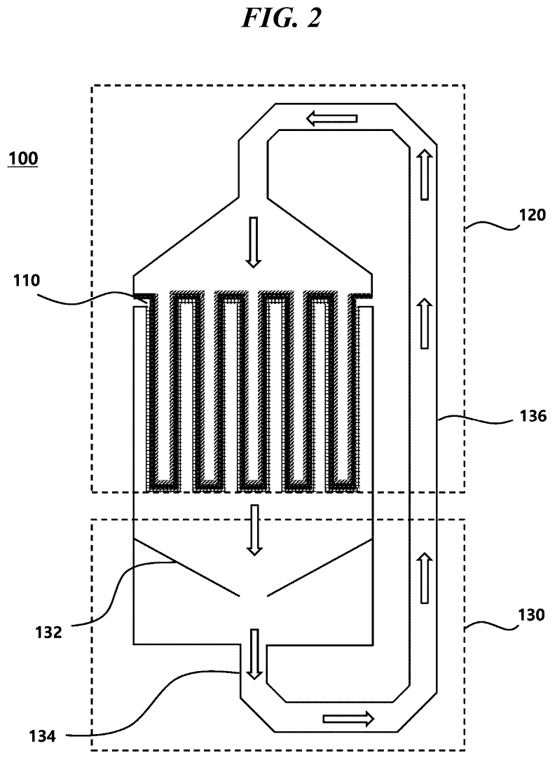

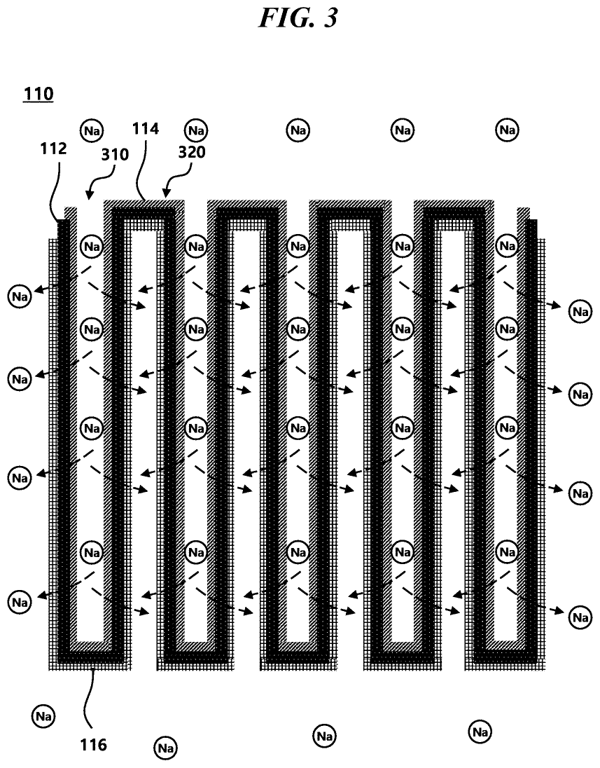

FIG. 2 is a configuration diagram of a thermal-to-electric converter according to an embodiment, and FIG. 3 is a diagram illustrating a thermal-to-electric conversion cell according to the embodiment.

Referring to FIGS. 2 and 3, the thermal-to-electric converter 100 may include a thermal-to-electric conversion cell 110, a high temperature portion 120, and a low temperature portion 130.

The thermal-to-electric conversion cell 110 may include three layers including a solid electrolyte layer 112, an anode layer 114, and a cathode layer 116.

The anode layer 114 may be brought into contact with one side of the solid electrolyte layer 112, and the cathode layer 116 may be brought into contact with the other side of the solid electrolyte layer 112.

Alkali metal particles (for example, sodium (Na) particles) oxidized in the anode layer 114 may move in the form of alkali metal ions through the solid electrolyte layer 112, be reduced in the cathode layer 116, and then be discharged from the thermal-to-electric conversion cell 110.

The anode layer 114 and/or the cathode layer 116 may be made as a porous electrode, and the porous electrode may include at least one of Mo, Ni, Al, PtW, RhW TiC, TIN, SiN, RuO, Ru2O, RuW, and NbC.

As a solid electrolyte, beta alumina-based solid electrolyte or NASICON-based solid electrolyte can be used.

The thermal-to-electric conversion cell 110 is also called a BASE, and the BASE may be an abbreviation for “Boehmite-Alumina-Sodium Electrolyte” or “Beta double prime Alumina Solid Electrolyte.” The BASE may represent an electrolyte layer that is one of key components of a thermal-to-electric converter. In the thermal-to-electric converter, the electrolyte layer serves to transfer heat and electricity. This layer is a core space for converting heat into electricity within the electrolyte, and may be made of an electrolyte containing sodium alkali metal. The BASE can be made of a mixture of alumina and boehmite, the alumina can improve the thermal conductivity of the electrolyte layer, and boehmite can provide structural stability and fire resistance. A combination of these materials can enable efficient thermal-to-electric conversion while maintaining the electrolyte layer of the thermal-to-electric converter stable. However, in the present embodiment, the thermal-to-electric conversion cell 110 is not limited to the BASE.

The thermal-to-electric converter 100 may include the high temperature portion 120 that supplies a high temperature and high pressure alkali metal fluid to the anode layer 114 of the thermal-to-electric conversion cell 110. The thermal-to-electric converter 100 may include the low temperature portion 130 that puts the alkali metal fluid discharged from the cathode layer 116 of the thermal-to-electric conversion cell 110 into a low temperature and pressure state and condenses the alkali metal fluid.

Here, the alkali metal fluid may be sodium (Na), potassium (K), or lithium (Li).

The high temperature and high pressure alkali metal fluid may supply electrons to an external cathode while being oxidized in the anode layer 114. The alkali metal fluid may be reduced by moving through the thermal-to-electric conversion cell 110 in the form of alkali metal ions and receiving electrons from an external anode at the cathode layer 116.

In the thermal-to-electric converter 100, an area for supplying and receiving electrons can increase when an exposed area of the anode layer 114 and an exposed area of the cathode layer 116 in which the alkali metal fluid is oxidized and reduced are larger, and thus, an output can be increased.

In the thermal-to-electric converter 100 according to the embodiment, the thermal-to-electric conversion cell 110 may be configured to have a convex-concave shape in which concave portions 310 and convex portions 320 appear alternately in order to increase an effective ionization area.

When viewed from above, the anode layer 114 may be disposed on the inner side of the concave portion 310, and the solid electrolyte layer 112 may be disposed in contact with the anode layer 114. The cathode layer 116 may be disposed in contact with the solid electrolyte layer 112. Since the concave portion 310 has a depth in a longitudinal direction, an effective ionization area, that is, an exposure area of the anode layer 114 increases.

The convex portion 320 may be disposed next to the concave portion 310. When the upper side of the concave portion 310 is in an open state and the lower side thereof is in a closed state, the convex portion 320 is in a closed state on the upper side and in an open state on the lower side. When the convex portion 320 is viewed from below, the cathode layer 116 may be disposed on the inner side, and the solid electrolyte layer 112 may be disposed in contact with the cathode layer 116. The anode layer 114 may be disposed in contact the solid electrolyte layer 112. Since the convex portion 320 has a depth in a longitudinal direction, an effective ionization area, that is, exposure area of the cathode layer 116 increases.

The alkaline metal fluid may be oxidized through the inner side of the concave portion 310, and reduced and discharged through the inner side of the convex portion 320. Since the concave portions 310 and the convex portions 320 are alternately disposed, there is an effect that a total effective ionization area of the thermal-to-electric conversion cell 110 increases.

The high temperature portion 120 may be formed to include the thermal-to-electric conversion cell 110. Although not shown in the drawing, a heat supply unit (not shown) may be disposed to surround top and side surfaces of the high temperature portion 120. Here, a high temperature sodium fluid from nuclear power generation may be supplied to the heat supply unit (not shown).

In the high temperature portion 120, the alkali metal fluid may maintain a high temperature and pressure state, and in some embodiments, the alkali metal fluid may come into contact with the anode layer 114 of the thermal-to-electric conversion cell 110 in a form molten in the high temperature portion 120.

The low temperature portion 130 may be disposed on the lower side of the thermal-to-electric converter 100. A member that absorbs or radiates heat may be disposed in the low temperature portion 130, and the alkali metal fluid losing heat in the heat absorbing or radiating member may condense and then move to the high temperature portion 120 through a condensation pipe 134.

A funnel structure 132 having an upper portion wider than a lower portion may be disposed on the upper side of the condensation pipe 134. An outlet of the funnel structure 132 may be disposed in line with an inlet of the condensation pipe 134 in a longitudinal direction. Accordingly, the alkali metal fluid collected in the funnel structure 132 can naturally flow into the condensation pipe 134.

A capillary circulation wick 136 is connected to the condensation pipe 134, and the alkali metal fluid can be moved to the high temperature portion 120 on the upper side by the capillary circulation wick 136.

The capillary circulation wick 136 may be formed of a material or structure that serves to absorb and move the alkali metal fluid. The capillary circulation wick 136 may be made in a form of fiber, foam, mesh, or the like, and can absorb and move an injected fluid. A material of the capillary circulation wick 136 may have a porous structure, and the alkali metal fluid may penetrate the porous structure of the capillary circulation wick 136 and move along the capillary circulation wick 136 due to a coupling action inside the fluid.

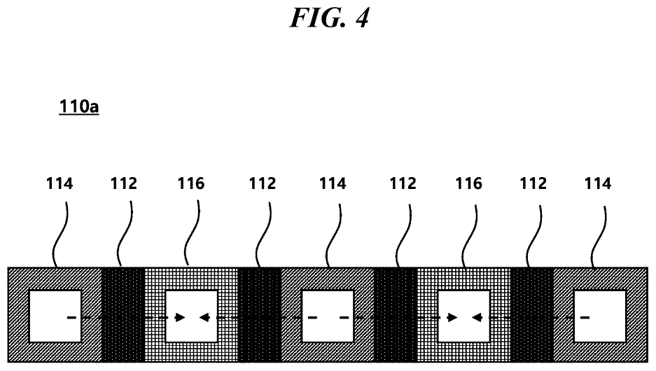

FIG. 4 is a cross-sectional view of a first example of the thermal-to-electric conversion cell according to the embodiment.

Referring to FIG. 4, in one cross section of a thermal-to-electric conversion cell 110a, anode layers 114 and cathode layers 116 may be alternately disposed in one direction. A solid electrolyte layer 112 may be disposed between the anode layer 114 and the cathode layer 116.

For example, the anode layer 114 may be disposed, the solid electrolyte layer 112 may be disposed in contact with the anode layer 114 in one direction, and the cathode layer 116 may be disposed in contact with the solid electrolyte layer 112.

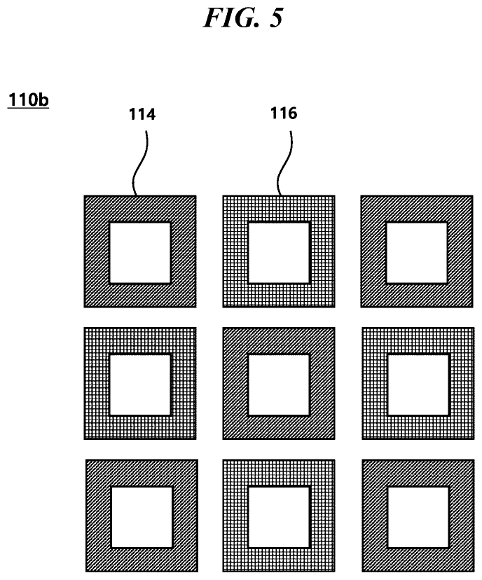

FIG. 5 is a cross-sectional view of a second example of the thermal-to-electric conversion cell according to the embodiment.

Referring to FIG. 5, in a thermal-to-electric conversion cell 110b, a plurality of anode layers 114 and a plurality of cathode layers 116 may be alternately disposed in a horizontal direction and a vertical direction.

When the thermal-to-electric conversion cell 110b is viewed from above, a portion where the anode layer 114 is located may appear as a concave portion, and a portion where the cathode layer 116 is located may appear as a convex portion. Accordingly, when an appearance of the thermal-to-electric conversion cell 110b is viewed from above, a plurality of concave portions and a plurality of convex portions may alternately appear in the horizontal direction and the vertical direction. Although not shown in the drawing, a solid electrolyte layer is disposed between the anode layer 114 and the cathode layer 116.

According to the second example, the alkali metal fluid injected into the anode layer 114 from the high temperature portion may be discharged to the cathode layer 116 while moving in all directions, including horizontal and vertical directions.

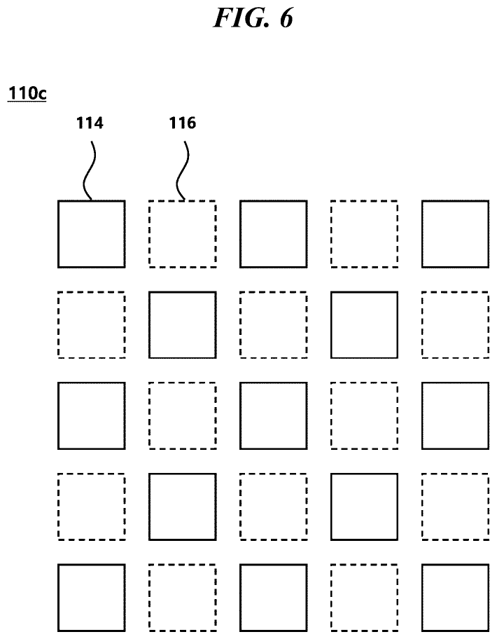

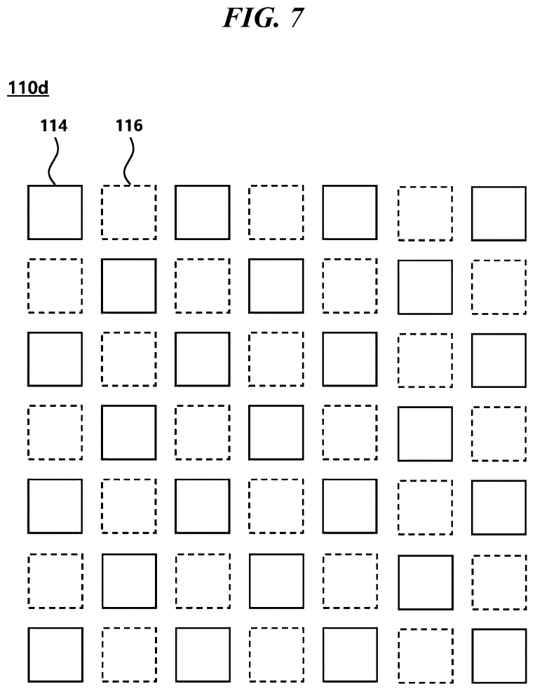

FIG. 6 is a cross-sectional view of a third example of the thermal-to-electric conversion cell according to the embodiment, and FIG. 7 is a cross-sectional view of a fourth example of the thermal-to-electric conversion cell according to the embodiment.

Referring to FIGS. 6 and 7, in thermal-to-electric conversion cells 110c and 110d, a plurality of anode layers 114 and a plurality of cathode layers 116 may be disposed in a square N×N matrix (N is a natural number equal to or greater than 3).

When thermal-to-electric conversion cells 110c and 110d are viewed from above, a portion where the anode layer 114 is located may appear as a concave portion, and a portion where the cathode layer 116 is located may appear as a convex portion. Accordingly, when an appearance of the thermal-to-electric conversion cells 110c and 110d is viewed from above, a plurality of concave portions and a plurality of convex portions may have a square N×N matrix form. Although not shown in the drawing, a solid electrolyte layer is disposed between the anode layer 114 and the cathode layer 116.

According to the third and fourth examples, the alkali metal fluid injected into the anode layer 114 in the high temperature portion may be discharged to the cathode layer 116 while moving in all directions, including horizontal and vertical directions.

Meanwhile, the high temperature portion may be disposed on the upper side, and the low temperature part may be disposed on the lower side. When viewed from above, only the anode layer 114 may be exposed, and when viewed from below, only the cathode layer 116 may be exposed. When the anode layer 114 and the cathode layer 116 are exposed in one direction, current collection at an anode and a cathode can be facilitated.

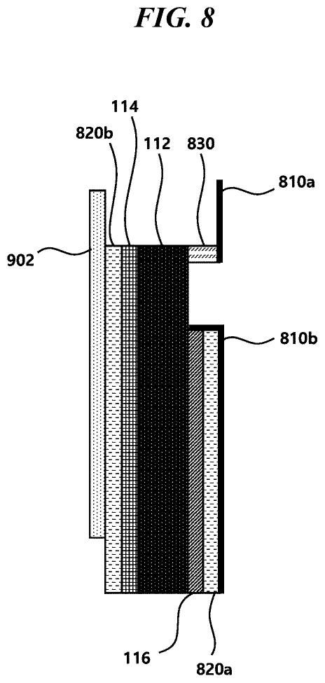

FIG. 8 is a diagram illustrating a current collection structure according to one embodiment.

Referring to FIG. 8, the anode layer 114 may be disposed on one side of the solid electrolyte layer 112, and the cathode layer 116 may be disposed on the other side.

A cathode current collection foam 820b may be disposed in contact with the anode layer 114, and an anode current collection foam 820a may be disposed in contact with the cathode layer 116.

The cathode current collection foam 820b and the anode current collection foam 820a may be made of, for example, a metallic material having a porous structure. For example, the cathode current collection foam 820b and the anode current collection foam 820a may be porous nickel foams coated with a lithium compound. The foams can pass a gas or fluid, and can be made of a nickel powder or binder. Since the porous nickel foam has a high surface area, has high electrical conductivity, and is able to pass an alkali metal fluid in a gas or fluid state, the porous nickel foam may be suitable as a current collector for the thermal-to-electric conversion cell according to the embodiment.

The cases 810a and 810b of the thermal-to-electric converter may be physically coupled to the solid electrolyte layer 112 and support the solid electrolyte layer 112.

The lower case 810b may be coupled to the outermost solid electrolyte layer 112 and brought into electrical contact with the outermost anode current collection foam 820a. The lower case 810b may be disposed to surround the thermal-to-electric conversion cell from the side and surround the low temperature portion on the lower side. This lower case 810b may be made of a conductive material such as a metallic material.

An insulator 830 may be disposed between the upper case 810a and the thermal-to-electric conversion cell. For example, the upper case 810a may be physically coupled to the outermost solid electrolyte layer 112 through the insulator 830. The upper case 810a may be disposed to surround the high temperature portion. The upper case 810a may be made of a conductive material such as a metallic material and may be electrically connected to the lower case 810b. Alternatively, the upper case 810a may remain insulated from the lower case 810b in some embodiments.

A cathode current collection pin 902 may come into contact with the cathode current collection foam 820b, and an anode current collection pin (not shown) may come into contact with the anode current collection foam 820a.

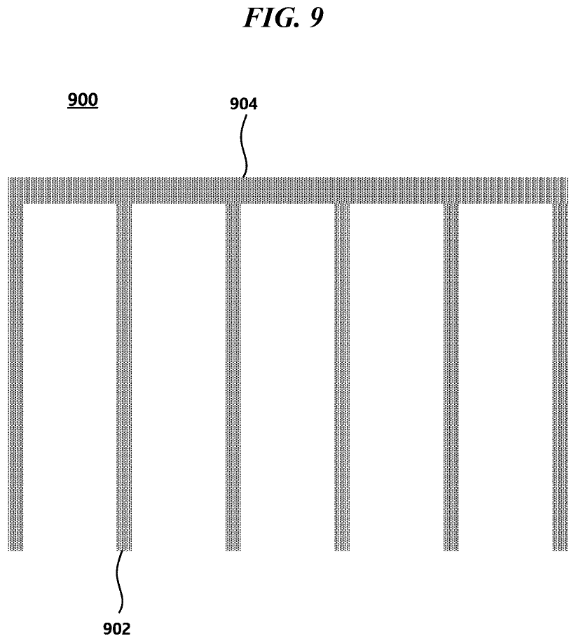

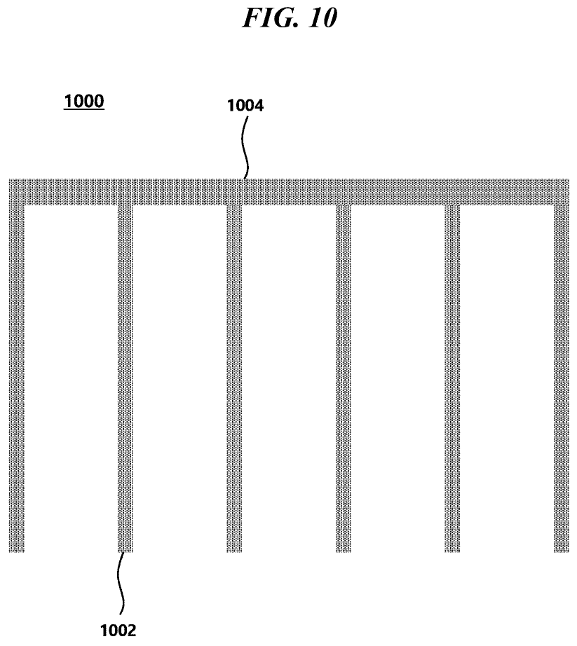

FIG. 9 is a cross-sectional view of a cathode current collection structure according to an embodiment, and FIG. 10 is a cross-sectional view of an anode current collection structure according to an embodiment.

Referring to FIGS. 9 and 10, the thermal-to-electric converter may further include a cathode current collection structure 900 in which a plurality of cathode current collection pins 902 are formed, and an anode current collection structure 1000 in which a plurality of anode current collection pins 1002 are formed.

The cathode current collection structure 900 may include a cathode current collection plate 904 having a plate shape or a mesh shape. A plurality of cathode current collection pins 902 may be formed on the cathode current collection plate 904 to protrude in a direction perpendicular to a plane formed by the cathode current collection plate 904.

The plurality of cathode current collection pins 902 may be inserted into the plurality of concave portions and brought into contact with the anode layer when viewed from the high temperature portion side.

The anode current collection structure 1000 may include an anode current collection plate 1004 having a plate shape or a mesh shape. A plurality of anode current collection pins 1002 may be formed on the anode current collection plate 1004 to protrude in a direction perpendicular to a plane formed by the anode current collection plate 1004.

The plurality of anode current collection pins 1002 may be inserted into the plurality of concave portions and brought into contact with the cathode layer when viewed from the low temperature portion side.

As described above, according to the present embodiment, it is possible to provide a large-capacity thermal-to-electric converter by increasing the effective ionization area of the thermal-to-electric conversion cell. According to the present embodiment, it is possible to provide a thermal-to-electric converter capable of easily achieving current collection while having a large effective ionization area.

Since terms such as “include,” “configure,” or “have” used above mean that relevant component may be included unless specifically stated otherwise, the terms should be construed as being able to further include other components, rather than excluding other components. All terms including technical or scientific terms have the same meaning as generally understood by those skilled in the art in the technical field to which the present disclosure pertains unless otherwise defined. Commonly used terms such as terms defined in a dictionary should be construed as having meanings consistent with meanings in the context of the related art, and should not be construed as idealized or overly formal meanings unless explicitly defined in the present disclosure.

The above description is merely an illustrative description of the technical idea of the present disclosure, and various modifications and variations can be made by those skilled in the art without departing from the essential characteristics of the present disclosure. Accordingly, the embodiments disclosed in the present disclosure are not intended to limit the technical idea of the present disclosure, but are for illustrative purposes, and the scope of the technical idea of the present disclosure is not limited by the embodiments. The scope of protection of the present disclosure should be construed according to the claims below, and all technical ideas within the equivalent scope should be construed as being included in the scope of rights of the present disclosure.

### National Research and Development Project Supporting the Invention

Project number: NP2020-0083-3
Ministry name: Ministry of Science and ICT
Project management organization: National Research Council of Science and Technology
Research project name: Creative convergence research project
Research project name: Development of key elements and new source technology for alkali metal ion direct thermal-to-electric conversion
Contribution rate: 1/1
Name of project execution organization: Korea Atomic Energy Research Institute
Research period: Aug. 10, 2022˜Aug. 9, 2023

What is claimed is:

1. An alkali metal thermal-to-electric converter comprising:
a thermal-to-electric conversion cell including three layers of an anode layer, a solid electrolyte layer, and a cathode layer and having a convex-concave shape with alternately appearing concave and convex portions, the thermal-to-electric conversion cell being configured to move alkali metal ions through the solid electrolyte layer;
a high temperature portion configured to supply a high temperature alkali metal fluid to the anode layer of the thermal-to-electric conversion cell; and
a low temperature portion configured to condense the alkaline metal fluid discharged to the cathode layer of the thermal-to-electric conversion cell to a low temperature and move the alkaline metal fluid to the high temperature portion.

2. The alkali metal thermal-to-electric converter of claim 1, wherein in the thermal-to-electric conversion cell, a plurality of concave portions and a plurality of convex portions alternately appear in a horizontal direction and a vertical direction.

3. The alkali metal thermal-to-electric converter of claim 2, wherein in the thermal-to-electric conversion cell, the plurality of concave portions and the plurality of convex portions have a square matrix form of one of 3×3, 5×5, and 7×7.

4. The alkali metal thermal-to-electric converter of claim 1, wherein the high temperature portion is disposed on the upper side and the low temperature portion is disposed on the lower side.

5. The alkali metal thermal-to-electric converter of claim 4, wherein the alkali metal fluid condensing in the low temperature portion is moved to the high temperature portion through a capillary circulation wick.

6. The alkali metal thermal-to-electric converter of claim 5, wherein the capillary circulation wick is connected to a condensation tube formed in the low temperature portion, and a funnel structure having an upper portion wider than a lower portion is disposed on the upper side of the condensation tube.

7. The alkali metal thermal-to-electric converter of claim 1, wherein a porous anode current collector is disposed in contact with the cathode layer of the thermal-to-electric conversion cell, and a porous cathode current collector is disposed in contact with the anode layer.

8. The alkali metal thermal-to-electric converter of claim 7, wherein a conductive lower case comes into contact with the outermost anode current collector.

9. The alkali metal thermal-to-electric converter of claim 8, wherein an insulator is disposed between the thermal-to-electric conversion cell and an upper case.

10. The alkali metal thermal-to-electric converter of claim 1, further comprising:
a cathode current collection structure having a plurality of cathode current collection pins inserted into a plurality of concave portions when viewed from the high temperature portion side.

11. The alkali metal thermal-to-electric converter of claim 10, further comprising:
an anode current collection structure having a plurality of anode current collection pins inserted into a plurality of concave portions when viewed from the low temperature portion side.

12. The alkali metal thermal-to-electric converter of claim 1, wherein the alkali metal fluid is sodium (Na) or potassium (K).

13. The alkali metal thermal-to-electric converter of claim 1, wherein a heat supply unit is disposed to surround upper and side surfaces of the high temperature portion.

14. The alkali metal thermal-to-electric converter of claim 13, wherein a high temperature sodium fluid from nuclear power generation is supplied to the heat supply unit.

15. The alkali metal thermal-to-electric converter of claim 1, wherein in the high temperature portion, the alkali metal fluid comes into contact with the anode layer of the thermal-to-electric conversion cell in a molten form.
